(19) United States
(12) Patent Application Publication
(10) Pub. No.: US 2020/0048498 A1
(43) Pub. Date: Feb. 13, 2020

(54) CHEMICAL MECHANICAL POLISHING SLURRY COMPOSITION

(71) Applicant: Dongjin Semichem Co., Ltd., Incheon (KR)

(72) Inventors: Hyejung Park, Hwaseong, Gyeonggi-do (KR); Mingun Lee, Hwaseong, Gyeonggi-do (KR); Chang Yong Park, Hwaseong, Gyeonggi-do (KR); Min-Sung Park, Hwaseong, Gyeonggi-do (KR); Sunghoon Jin, Hwaseong, Gyeonggi-do (KR); Goo-Hwa Lee, Hwaseong, Gyeonggi-do (KR); Jongdai Park, Hwaseong, Gyeonggi-do (KR); Jaehyun Kim, Hwaseong, Gyeonggi-do (KR)

(21) Appl. No.: 16/604,035

(22) PCT Filed: Feb. 22, 2018
(86) PCT No.: PCT/KR2018/002206

§ 371 Date: Oct. 9, 2019

(30) Foreign Application Priority Data
Apr. 27, 2017 (KR) 10-2017-0054609
Feb. 21, 2018 (KR) 10-2018-0020654

(51) Int. Cl. C09G 1/02; H01L 21/321

(52) U.S. Cl. CPC C09G 1/02; H01L 21/3212

(57) ABSTRACT

The present invention relates to a chemical mechanical polishing slurry composition, and more specifically, to a chemical mechanical polishing slurry composition that can polish an insulating film such as a silicon nitride film or a metal film such as tungsten alone or simultaneously, and particularly, can easily control the polishing speed, and thus minimize an interlayer step difference of a semiconductor device by using a compound having a phosphate group as an agent for controlling polishing selectivity, and selectively using a tertiary amine compound together with the agent for controlling polishing selectivity, and a method for polishing a semiconductor substrate using the same.

### CROSS-REFERENCE TO RELATED APPLICATION

This application claims the benefit of Korean Patent Application No. 10-2017-0054609 filed on Apr. 27, 2017 and Korean Patent Application No. 10-2018-0020654 filed on Feb. 21, 2018 with the Korean Intellectual Property Office, the disclosures of which are herein incorporated by reference in their entirety.

### TECHNICAL FIELD

The present invention relates to a chemical mechanical polishing slurry composition, more specifically, to a chemical mechanical polishing slurry composition capable of controlling polishing selectivity by including a phosphate compound as an agent for controlling polishing selectivity, and a method for polishing a semiconductor substrate using the same.

### BACKGROUND ART

With the high integration, high density, and multilayer structure of semiconductor devices, a technology of forming finer patterns is being used, and thus the surface structure of a semiconductor device is becoming complicated, and a step difference of interlayer films is increasing more and more.

If a step difference is generated in interlayer films, process defects may be generated in the manufacturing process of a semiconductor device, and thus, it is important to minimize the step difference. Thus, a technology for planarization of a semiconductor substrate is being used so as to reduce the step difference of interlayer films.

In the technology of planarization of a semiconductor substrate, reactive ion etching, chemical mechanical polishing (CMP), and the like are used to remove a metal such as tungsten in a semiconductor process. Since the reactive ion etching process has a problem of generating residues on the semiconductor substrate after conducting the process, chemical mechanical polishing is being used more frequently.

The chemical mechanical polishing uses a water soluble slurry composition including an abrasive and the like to polish a semiconductor substrate.

In case an insulating film, a metal film, and a multilayer including an insulating film and a metal film are polished with the slurry composition, different polishing rates of each polished film becomes a problem.

### DETAILED DESCRIPTION OF THE INVENTION

### Technical Problems

It is an object of the present invention to provide a chemical mechanical polishing slurry composition that can more easily control the polishing speed of an insulating film of a semiconductor substrate than before, and thus can control polishing selectivity by including a specific polishing selectivity controlling agent.

It is another object of the present invention to provide a method for polishing a semiconductor substrate using the above slurry composition, which can polish the insulating film and metal film of the semiconductor substrate alone or simultaneously.

### Technical Solutions

The chemical mechanical polishing slurry composition according to one embodiment of the present invention includes:

1) an abrasive; and
2) an agent for controlling polishing selectivity selected from the group consisting of a) a compound having one or more phosphate groups selected from the group consisting of a cyclic compound having a phosphate group, an inorganic compound having a phosphate group, and a metal compound having a phosphate group, b) a tertiary amine compound, and c) a mixture thereof.

More specifically, the agent for controlling polishing selectivity may be a cyclic compound having a phosphate group.

Such an agent for controlling polishing selectivity may be an agent for controlling the polishing selectivity of a silicon nitride film used to control the polishing speed of a silicon nitride film.

In this case, in the agent for controlling polishing selectivity, the mixture of c) may include the compounds of a) and the tertiary amine compound of b) at a weight ratio of 1:0.25 to 1:5.

The slurry composition according to one embodiment of the present invention may further include a catalyst.

The slurry composition according to one embodiment of the present invention may further include one or more pH adjusting agents.

The slurry composition according to one embodiment of the present invention may further include one or more biocides.

The slurry composition according to one embodiment of the present invention may further include one or more reaction controllers.

The slurry composition according to one embodiment of the present invention may further include water, alcohol, or a mixture thereof.

The slurry composition according to one embodiment of the present invention may further include one or more oxidizing agents.

The cyclic compound having a phosphate group may be one or more selected from the group consisting of inositol monophosphate, inositol biphosphate, inositol triphosphate, inositol tetraphosphate, inositol pentakisphosphate, inositol hexaphosphate, glucose 1-phosphate, and glucose 6-phosphate.

The tertiary amine compound may be one or more selected from the group consisting of trimethylamine, triethylamine, tributylamine, and tripropylamine.

In the present invention, the abrasive may be included in the content of 0.01 to 10 wt %, based on the total weight of the slurry composition.

The catalyst may be included in the content of 0.00001 to 1 wt %, based on the total weight of the slurry composition.

The agent for controlling polishing selectivity may be included in the content of 0.0001 to 10 wt %, based on the total weight of the slurry composition.

The chemical mechanical polishing slurry composition according to another embodiment of the present invention includes, based on the total weight of the slurry composition, 0.01 to 10 wt % of an abrasive, 0.0001 to 10 wt % of an agent for controlling polishing selectivity, 0.00001 to 1 wt % of a catalyst, 0.0005 to 5 wt % of a pH adjusting agent, 0.0001 to 0.1 wt % of a biocide, and the remaining amount of water.

The slurry composition may further include one or more reaction controller in the content of 0.0001 to 1 wt %, based on the total weight of the slurry composition, and may further include an oxidizing agent in the content of 0.005 to 10 wt %, based on the total weight of the slurry composition.

Meanwhile, a method for polishing a semiconductor substrate according to yet another embodiment of the present invention includes:
a) a process of polishing an insulating film or a metal film formed on a semiconductor substrate; or
b) a process of simultaneously polishing an insulating film and a metal film formed on a semiconductor substrate,

using the above-explained chemical mechanical polishing slurry composition.

The insulating film may include a silicon nitride film, a silicon oxide film, or both a silicon nitride film and a silicon oxide film. The metal film may be a tungsten film.

In the process of b), in case the insulating film is a silicon nitride film or a silicon oxide film, polishing selectivity of the silicon nitride film or silicon oxide film:metal film may be 1:3 or more.

In the process of b), in case the insulating film includes a silicon nitride film and a silicon oxide film, polishing selectivity of the silicon nitride film:silicon oxide film:metal film may be 1:0.5 to 2:3 to 10.

### Advantageous Effects

The slurry composition of the present invention can polish an insulating film including a silicon nitride film, a silicon oxide film, and the like, or a metal film including tungsten on a semiconductor substrate alone or simultaneously, and exhibit excellent effects, by using a compound having a phosphate group, and selectively further using a tertiary amine compound as an agent for controlling polishing selectivity. That is, by using the slurry composition of the present invention, the compound having a phosphate group can selectively increase the polishing speed of an insulating film, particularly, the polishing speed of a silicon nitride film. Further, the tertiary amine compound that can be used as an agent for controlling polishing selectivity can increase the polishing speed of an insulating film, particularly, the polishing speed of a silicon oxide film. Additionally, by appropriately combining the contents of the agents for controlling polishing selectivity, polishing can be simultaneously achieved for a film consisting of three kinds such as a silicon nitride film, a silicon oxide film, and tungsten, and thus the selectivity thereof can be easily controlled.

### DETAILED DESCRIPTION OF EMBODIMENTS

Although various modifications can be made to the present invention and the present invention may have various forms, specific examples will be illustrated and explained in detail below. However, it should be understood that these are not intended to limit the present invention to specific disclosures, and that the present invention includes all the modifications, equivalents, or replacements thereof without departing from the spirit and technical scope of the invention.

A singular expression includes a plural expression thereof, unless it is expressly stated or obvious from the context that such is not intended. As used herein, the terms “comprise”, “have”, etc. are intended to designate the existence of a practiced characteristic, number, step, constructional element, or combinations thereof, and they are not intended to preclude the possibility of existence or addition of one or more other characteristics, numbers, steps, constructional elements, or combinations thereof.

Hereinafter, a chemical mechanical polishing slurry composition (CMP composition) and a method for polishing a semiconductor substrate using the same according to the present invention will be explained in detail.

Chemical Mechanical Polishing Slurry Composition

According to one embodiment of the present invention, a chemical mechanical polishing slurry composition is provided, which includes: 1) an abrasive; and 2) an agent for controlling polishing selectivity selected from the group consisting of a) a compound having one or more phosphate groups selected from the group consisting of a cyclic compound having a phosphate group, an inorganic compound having a phosphate group, and a metal compound having a phosphate group, b) a tertiary amine compound, and c) a mixture thereof.

That is, the present invention presents a slurry composition capable of controlling selectivity, and a method for polishing a semiconductor substrate using the same.

Using the slurry composition of the present invention, an insulating film or a metal film can be polished alone, or they may be polished simultaneously. Herein, the insulating film may include an insulating film consisting of one kind of a silicon nitride film or a silicon oxide film, and an insulating film consisting of two kinds of a silicon nitride film and a silicon oxide film, formed on a semiconductor substrate. The metal film may include a film of one or more kinds of metals, more specifically, a tungsten film, formed on a semiconductor substrate.

For this purpose, the present invention uses the above-explained compounds of a) to c), as an agent for controlling polishing selectivity in the slurry composition.

As the compound of a), a compound having a phosphate group is used, and specifically, one or more selected from the group consisting of above-explained three components are used. More specifically, the most effective polishing selectivity controlling agent, based on the same content, may be a cyclic compound having a phosphate group, which may include an alicyclic compound.

Such an agent for controlling polishing selectivity of a) may effectively increase the polishing speed of a silicon nitride film, among insulating films. Thus, the agent for controlling polishing selectivity may be an agent for controlling polishing selectivity of a silicon nitride film used to control the polishing speed of a silicon nitride film. The agent for controlling polishing selectivity can further increase the polishing speed of a silicon nitride film according to the content used.

Herein, the cyclic compound having a phosphate group may have a carbon number of 4 to 7. For example, the cyclic compound having a phosphate group used as the agent for controlling polishing selectivity may be an alicyclic compound, and specifically, it may be one or more selected from the group consisting of inositol monophosphate, inositol biphosphate, inositol triphosphate, inositol tetraphosphate, inositol pentakisphosphate, inositol hexaphosphate, glucose 1-phosphate, and glucose 6-phosphate of the following structures.

Inositol monophosphate, IP

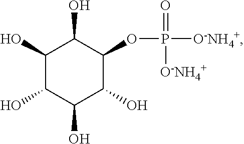

Inositol bisphosphate, IP₂

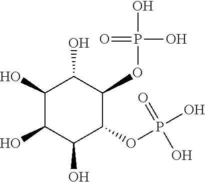 [SMILES: O=P(O)(O)O[C@@H]1[C@@H](O)[C@H](O)[C@H](O)[C@H](O)[C@H]1OP(=O)(O)O]

Inositol trisphosphate, IP₃

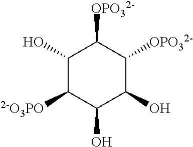

Inositol tetraphosphate, IP₄

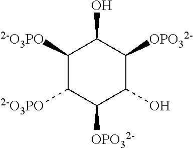

Inositol pentakisphosphate, IP₅

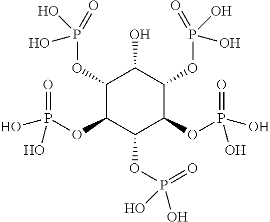 [SMILES: O=P(O)(O)O[C@@H]1[C@@H](OP(=O)(O)O)[C@H](OP(=O)(O)O)[C@H](O)[C@H](OP(=O)(O)O)[C@H]1OP(=O)(O)O]

Inositol hexaphosphate, IP₆ (phytic acid or phytate)

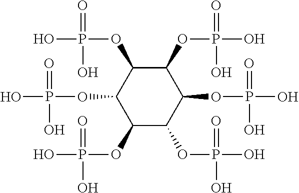 [SMILES: O=P(O)(O)O[C@H]1[C@H](OP(=O)(O)O)[C@@H](OP(=O)(O)O)[C@H](OP(=O)(O)O)[C@@H](OP(=O)(O)O)[C@H]1OP(=O)(O)O]

Glucose 1-phosphate

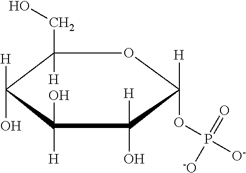

Glucose 6-phosphate

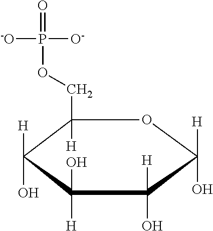

The inorganic compound having a phosphate group may include monoammonium phosphate MAP), diammonium phosphate (DSP), triammonium phosphate (TSP), and the like, and one or more kinds thereof may be selected and used.

The metal compound having a phosphate group may include monosodium phosphate (MSP), disodium phosphate (DSP), trisodium phosphate (TSP), and the like, and one or more kinds thereof may be selected and used.

According to another embodiment of the present invention, as the agent for controlling polishing selectivity, the b) tertiary amine compound may be used. Further, the agent for controlling polishing selectivity may be a mixture of a) one or more compounds selected from the above-explained compounds having phosphate groups, and the b) tertiary amine compound.

When using a tertiary amine compound as an agent for controlling polishing selectivity, the polishing speed of a silicon oxide film may be increased. In case an insulating film consists of a silicon nitride film and a silicon oxide film, the polishing speeds of the silicon nitride film and the silicon oxide film can be simultaneously controlled.

The tertiary amine compound may include trimethylamine, triethylamine, tributylamine, tripropylamine, and the like, and one or more selected therefrom may be used.

Herein, if a primary amine compound or a secondary amine compound is used instead of the tertiary amine compound, it may be difficult to increase the polishing speed of a metal film (for example, a silicon oxide film) of a semiconductor substrate, and if a polyamine compound is used instead of the tertiary amine compound, the dispersibility of silica used as an abrasive may be deteriorated, thus generating precipitation.

According to one embodiment of the present invention, in case the construction of c) is used as an agent for controlling polishing selectivity, the c) may include the a) compound having a phosphate group and the b) tertiary amine compound at a weight ratio of 1:0.25 to 1:5. If the weight ratio of the a) compound having a phosphate group and the b) tertiary amine compound is less than 1:0.25, the polishing selectivity of a silicon oxide film may be lowered, compared to a silicon nitride film. Further, if the ratio exceeds 1:5, the polishing selectivity of a silicon oxide film may excessively increase, compared to a silicon nitride film, and thus erosion may be generated.

More specifically, in case the agent for controlling polishing selectivity is c), the a) cyclic compound having a phosphate group and the b) tertiary amine compound may be included at a weight ratio of 1:0.7 to 1:3. In case both substances are used in the above range, selectivity of a silicon nitride film:a silicon oxide film may be controlled to 1:0.5 to 2. However, if the above range is not fulfilled, it may be difficult to control polishing selectivity between a silicon nitride film and a silicon oxide film.

One selected from an inorganic compound having a phosphate group and a metal compound having a phosphate group, and the tertiary amine compound, may be included at a weight ratio of 1:0.25 to 1:5. In this case, it may be easy to control the polishing selectivity between a silicon nitride film and a silicon oxide film.

The content of the agent for controlling polishing selectivity may be in the range of 0.0001 to 10 wt %, specifically 0.0001 to 5 wt %, more specifically 0.0001 to 1 wt %, most specifically 0.0001 to 0.5 wt %, based on the total weight of the slurry composition. In case a tertiary amine compound is used, it may be used in the content of 0.0001 to 5 wt %, more preferably 0.0001 to 0.5 wt %, based on the total weight of the composition. If the content of the agent for controlling polishing selectivity is less than 0.0001 wt %, the effect of controlling a polishing speed may be insufficient, and if it is greater than 10 wt %, a polishing speed may not increase any longer.

Meanwhile, the slurry composition according to one embodiment of the present invention further includes an abrasive together with the above-explained agent for controlling polishing selectivity.

Among common abrasives for mechanical polishing, the abrasive used in the slurry composition of the present invention may be colloidal silica or fumed silica. The content of the abrasive may be 0.01 to 10 wt %, specifically 0.1 to 8 wt %, based on the total weight of the composition. If the content of the abrasive is less than 0.01 wt %, a polishing speed may be lowered, and if it is greater than 10 wt %, scratches may be excessively generated.

The slurry composition according to one embodiment of the present invention may further include a catalyst.

The catalyst may increase the polishing speed of a metal film such as tungsten, and specifically, one or more selected from the group consisting of iron salts such as iron nitrate, iron chloride, and the like, and nano-ferrosilicon (FeSi) may be used.

The content of the catalyst may be 0.00001 to 1 wt %, specifically 0.0001 to 0.5 wt %, based on the total weight of the slurry composition. If the content of the catalyst is less than 0.00001 wt %, the polishing speed of a metal film may be lowered, and if it is greater than 1 wt %, the polishing speed may become non-uniform due to excessive chemical reactivity.

The slurry composition according to one embodiment of the present invention may further include one or more pH adjusting agents.

The pH range of the slurry composition of the present invention may be 1 to 4, specifically 1.5 to 3.5. Thus, the present invention can adjust the pH of the slurry composition using an acidic or basic pH adjusting agent during the reaction. If the pH range of the slurry composition is lower than 1, there may be a problem in terms of handling due to excessively low acidity, and if it is higher than 4, the polishing speed for some films may decrease.

The pH adjusting agent is used when adjusting the pH of the slurry composition, and one selected from the group consisting of an acidic adjusting agent and a basic adjusting agent may be used to adjust within the above pH range where handling is good and the polishing speed is excellent.

The acidic adjusting agent may include a nitrate, hydrochloric acid, a sulfate, and the like, and the basic adjusting agent may include potassium hydroxide, sodium hydroxide, tetramethyl ammonium hydroxide, and tetrabutyl ammonium hydroxide, and more specifically, tetramethyl ammonium hydroxide, tetrabutyl ammonium hydroxide, and the like. In semiconductor material, potassium and sodium are metal impurities that may induce wafer contamination and defects, and thus the amount of use is limitative.

The content of the pH adjusting agent may be 0.0005 to 5 wt %, specifically 0.001 to 1 wt %, based on the total weight of the slurry composition. If the content of the pH adjusting agent is less than 0.0005 wt %, the pH controlling effect may be insufficient, and if it is greater than 5 wt %, slurry performance may be changed.

The slurry composition according to one embodiment of the present invention may further include one or more biocides.

The biocide is used to prevent microorganism contamination, and for example, polyhexamethylene guanidine (PHMG), isothiazolinone compounds, and the like may be used. As the isothiazolinone compounds, one or more selected from the group consisting of methylisothiazolinone (MIT), chloromethyl isothiazolinone (OMIT), and 1,2-benzisothiazol-3(2H)-one (benzisothiazolinone, BIT) may be used.

The content of the biocide may be 0.0001 to 0.1 wt %, specifically 0.001 to 0.05 wt %, based on the total weight of the slurry composition.

If the content of the biocide is less than 0.0001 wt %, microorganisms may be generated due to insufficient sterilization, and if it is greater than 0.1 wt %, slurry performance may be changed.

The slurry composition according to one embodiment of the present invention may further include one or more reaction controllers. As the reaction controller, malonic acid, phosphoric acid, potassium iodate, and the like may be used. The content of the reaction controller may be 0.0001 to 1 wt %, specifically 0.001 to 0.5 wt %, based on the total weight of the slurry composition. If the content of the reaction controller is less than 0.0001 wt %, the non-uniformity of a substrate may increase, and if it is greater than 1 wt %, a polishing speed may be lowered.

The slurry composition according to one embodiment of the present invention may further include water, alcohol (ROH), or a mixture thereof, as the remaining components fulfilling 100 wt % of the composition, except the above-explained components. In case water is included, it may be ion exchange water, ultrapure water, or distilled water, and the distilled water may be generally obtained through primary to tertiary distillation. In this case, the slurry composition of the present invention may be a water soluble composition. As the alcohol, a linear or branched C2-10 alcohol may be used. The slurry composition may further include an organic solvent, as necessary. In this case, it may be used as a solubilizer of components hardly soluble in water, or used to improve wettability of the slurry composition to a polished film.

The slurry composition according to one embodiment of the present invention may further include an oxidizing agent.

The oxidizing agent may be further included in case a polishing subject includes tungsten.

The oxidizing agent may be preserved while included in the slurry composition, or it may be separated from the remaining slurry composition and preserved in the form of an additive solution so as to prevent a decrease in the stability of the slurry composition. In case the oxidizing agent is preserved in the form of an additive solution, it may be combined with the remaining slurry composition before coating on a polished film, or may be coated on a polished film independently from the slurry composition during polishing. Specific examples of the oxidizing agent that can be used may include hydrogen peroxide, potassium iodate, potassium permanganate, ammonia, amine compounds, ammonium compounds, nitrate compounds, and a mixture thereof, but are not limited thereto.

The content of the oxidizing agent may be 0.005 to 10 wt %, specifically 0.2 to 5 wt %, based on the total weight of the slurry composition.

If the content of the oxidizing agent is less than 0.005 wt %, the polishing speed of a metal film may decrease, and if it is greater than 10 wt %, the polishing speed of a metal film may become non-uniform due to excessive chemical reactivity.

The chemical mechanical polishing slurry composition according to another embodiment of the present invention may include, based on the total weight of the slurry composition, 0.01 to 10 wt % of an abrasive, 0.0001 to 10 wt % of an agent for controlling polishing selectivity, 0.00001 to 1 wt % of a catalyst, 0.0005 to 5 wt % of a pH adjusting agent, 0.0001 to 0.1 wt % of a biocide, and the remaining amount of water.

The slurry composition may further include a reaction controller in the content of 0.0001 to 1 wt %, based on the total weight of the slurry composition, and may further include an oxidizing agent in the content of 0.005 to 10 wt %, based the total weight of the slurry composition. In this case, the present invention may provide a chemical mechanical polishing slurry composition including 0.01 to 10 wt % of an abrasive, 0.0001 to 10 wt % of an agent for controlling polishing selectivity, 0.00001 to 1 wt % of a catalyst, 0.0005 to 5 wt % of a pH adjusting agent, 0.0001 to 0.1 wt % of a biocide, 0.0001 to 1 wt % of a reaction controller, and the remaining amount of water.

Method for Polishing a Semiconductor Substrate

According to another embodiment of the present invention, a method for polishing a semiconductor substrate is provided, which includes a) a process of polishing an insulating film or a metal film formed on a semiconductor substrate, or b) a process of simultaneously polishing an insulating film and a metal film formed on a semiconductor substrate, using the above-explained chemical mechanical polishing slurry composition.

The insulating film may include a silicon nitride film, a silicon oxide film, or both a silicon nitride film and a silicon oxide film. The metal film may include a tungsten film.

When polishing an insulating film alone, a catalyst and an oxidizing agent may not be included in the polishing slurry composition. Further, when simultaneously polishing an insulating film and a metal film, it may be advantageous for improvement in polishing efficiency that a catalyst and an oxidizing agent are included in the polishing slurry composition.

In addition, since the chemical mechanical polishing slurry composition of the present invention includes the above-explained polishing selectivity controlling agent in a specific content, a polishing speed may be quicker than before, and an insulating film or a metal film of a semiconductor substrate may be polished, or an insulating film and a metal film may be simultaneously polished.

Thus, the slurry composition of the present invention may be used to polish one selected from the group consisting of a silicon nitride film, a silicon oxide film or a tungsten film of a semiconductor substrate, or simultaneously polish two or three selected therefrom, and improve the polishing speed. Herein, in case the slurry composition is used to polish a metal film including a tungsten film, the above-explained oxidizing agent may be added to the slurry composition immediately before use.

For example, in the case of a slurry composition for polishing tungsten, a composition without hydrogen peroxide is prepared and stored as a 100% product, and hydrogen peroxide may be additionally mixed before CMP. The reason is that if a slurry composition is stored while including hydrogen peroxide, hydrogen peroxide may be decomposed and the content may not be maintained constant, thus shortening a product life cycle.

Specifically, although the polishing subject is not limited thereto, mainly, an insulating film such as a silicon oxide film (SiO₂), a silicon nitride film (Si₃N₄), or a metal film such as a tungsten film (W) constituting a semiconductor substrate may be respectively polished, or two or three films selected therefrom may be simultaneously polished.

In case the insulating film in the b) process is a silicon nitride film, the polishing selectivity of the silicon nitride film:metal film may be 1:3 or more, or 1:3 to 10, and specifically 1:4 to 8.

Additionally, in case the insulating film in the b) process includes a silicon nitride film and a silicon oxide film, the polishing selectivity of the silicon nitride film:silicon oxide film:metal film may be 1:0.5 to 2:3 to 10.

Hereinafter, the actions and effects of the invention will be explained through specific examples of the invention. However, these examples are presented only as the illustrations of the invention, and the scope of the right of the invention is not determined thereby.

### EXAMPLE

For examples and comparative examples, the polishing conditions and the measurement method of the polishing speed of a metal film of a semiconductor substrate are as follows.

1. Test Wafer: tungsten (W) 8 inch blanket, silicon oxide film (PE-TEOS) 8 inch blanket, silicon nitride film (Si₃N₄) 8 inch blanket

2. Polisher: Mirra 3400 (Applied Materials Corporation)

3. Polishing conditions: progressing by the method of Table 1

TABLE 1

| | | IC | RR | EC | UC | Slurry |
|---|---|---|---|---|---|---|
| platen | Head | pressure | pressure | pressure | pressure | flow |
| rpm | Rpm | psi | psi | psi | psi | ml/min |
| 84 | 78 | 3.6 | 10.4 | 5.2 | 5.2 | 200 |

4. Polishing pad: IC-1000 (Rohm & Haas)

5. Thickness (polishing speed) measuring device (thickness unit: Ångstrom, symbol: Å)

Tungsten film: CMT-2000 (4-point probe, Changmin Tech Co. Ltd.)

Silicon oxide film and silicon nitride film: Thermawave OP-2600 (KLA TENCOR)

Polishing speed=thickness before CMP—thickness after CMP [Equation 1]

6. Particle size analysis device

ELS-Z (Otsuka Electronics)

7. pH analysis device

Metrohm 704 (Metrohm)

### Comparative Examples 1 to 3 and Examples 1 to 11: Preparation of Slurry Including Compound Having a Phosphate Group

An abrasive (200 nm fumed silica), a catalyst (iron nitrate, ferrosilicon), an agent for controlling polishing selectivity (the component of Table 2), biocide (methylisothiazolinone), and distilled water were put into a mixer, stirred through a mechanical stirrer, and mixed.

After the stirring was completed, nitric acid and TMAH were used as pH adjusting agents to adjust the pH of the slurry composition to 2. Before polishing a semiconductor film, 3 wt % of 31% hydrogen peroxide was additionally added to the composition of which pH had been adjusted, thus preparing the slurry compositions of Examples 1 to 11.

Herein, the contents and components of the abrasive and polishing selectivity controlling agent were as shown in the following Table 2. A composition without an agent for controlling polishing selectivity was designated as Comparative Example 1.

The compositions wherein the contents of the polishing selectivity controlling agent do not fall within the scope of the present invention (0.0001 to 10 wt %) were respectively designated as Comparative Examples 2 and 3.

In the slurry composition, the content of biocide was 0.01 wt %, the contents and components of abrasive, catalyst, and polishing selectivity controlling agent were as shown in the following Table 2, nitric acid and TMAH were included such that the pH of the slurry composition became 2, and the content of distilled water was adjusted to the remainder.

TABLE 2

| | | | Agent for controlling | | | | |
|---|---|---|---|---|---|---|---|
| | Abrasive | | polishing selectivity | | Catalyst | | |
| | | content | | content | | content | |
| | kind | (wt %) | kind | (wt %) | component | (wt %) | pH |
| Compar- | silica | 7 | — | — | ferro- | 0.005 | 2 |
| ative | | | | | silicon | | |
| Example | | | | | | | |
| 1 | | | | | | | |
| Example | silica | 7 | inositol | 0.05 | ferro | 0.005 | 2 |
| 1 | | | monophosphate | | silicon | | |
| Compar- | silica | 7 | inositol | 0.00005 | ferro- | 0.005 | 2 |
| ative | | | hexaphosphate | | silicon | | |
| Example | | | | | | | |
| 2 | | | | | | | |
| Compar- | silica | 7 | inositol | 11 | ferro- | 0.005 | 2 |
| ative | | | hexaphosphate | | silicon | | |
| Example | | | | | | | |
| 3 | | | | | | | |
| Example | silica | 7 | inositol | 0.05 | ferro- | 0.005 | 2 |
| 2 | | | trisphosphate | | silicon | | |
| Example | silica | 7 | inositol | 0.0001 | ferro- | 0.005 | 2 |
| 3 | | | hexaphosphate | | silicon | | |
| Example | silica | 7 | inositol | 0.05 | ferro- | 0.005 | 2 |
| 4 | | | hexaphosphate | | silicon | | |
| Example | silica | 7 | inositol | 10 | ferro- | 0.005 | 2 |
| 5 | | | hexaphosphate | | silicon | | |
| Example | silica | 7 | Glucose 6- | 0.05 | ferro- | 0.005 | 2 |
| 6 | | | phosphate | | silicon | | |
| Example | silica | 7 | monoammonium | 0.05 | ferro- | 0.005 | 2 |
| 7 | | | phosphate | | silicon | | |
| Example | silica | 7 | Triammonium | 0.05 | ferro- | 0.005 | 2 |
| 8 | | | phosphate | | silicon | | |
| Example | silica | 7 | monosodium | 0.05 | ferro- | 0.005 | 2 |
| 9 | | | phosphate | | silicon | | |
| Example | silica | 7 | Trisodium | 0.05 | ferro- | 0.005 | 2 |
| 10 | | | phosphate | | silicon | | |
| Example | silica | 7 | Trisodium | 0.05 | Iron | 0.06 | 2 |
| 11 | | | phosphate | | nitrate | | |

For the slurry compositions of Comparative Examples 1 to 3 and Examples 1 to 11, polishing speeds were measured as explained above, and the results are shown in the following Table 3.

TABLE 3

| | | | | Selectivity | | |
|---|---|---|---|---|---|---|
| No. | Si₃N₄ | SiO₂ | W | Si₃N₄ | SiO₂ | W |
| Comparative | 145 | 310 | 1920 | 1.0 | 2.1 | 13.2 |
| Example 1 | | | | | | |
| Comparative | 150 | 322 | 1922 | 1.0 | 2.1 | 12.8 |
| Example 2 | | | | | | |
| Comparative | 699 | 308 | 2033 | 1.0 | 0.4 | 2.9 |
| Example 3 | | | | | | |
| Example 1 | 395 | 300 | 1907 | 1.0 | 0.8 | 4.8 |
| Example 2 | 390 | 304 | 1934 | 1.0 | 0.8 | 5.0 |
| Example 3 | 287 | 331 | 1897 | 1.0 | 1.2 | 6.6 |
| Example 4 | 395 | 311 | 1914 | 1.0 | 0.8 | 4.8 |
| Example 5 | 687 | 318 | 2095 | 1.0 | 0.5 | 3.0 |
| Example 6 | 379 | 318 | 1911 | 1.0 | 0.8 | 5.0 |
| Example 7 | 309 | 309 | 1927 | 1.0 | 1.0 | 6.2 |
| Example 8 | 315 | 328 | 1908 | 1.0 | 1.0 | 6.1 |
| Example 9 | 327 | 317 | 1918 | 1.0 | 1.0 | 5.9 |
| Example 10 | 339 | 311 | 1999 | 1.0 | 0.9 | 5.9 |
| Example 11 | 322 | 315 | 1944 | 1.0 | 1.0 | 6.0 |

As shown in Table 3, in case a slurry composition includes a compound having a phosphate group as an agent for controlling polishing selectivity like Examples 1 to 11, as the content increased, the polishing speed of a silicon nitride film increased, but the polishing speeds of a silicon oxide film and tungsten were not influenced.

Further, Examples 1 to 6 using cyclic compounds, among the compounds having phosphate groups, exhibited most excellent effects of improving the polishing speed of a silicon nitride film, based on the same content, and Examples 7 to 11 using an inorganic compound having a phosphate group or a metal compound having a phosphate group exhibited similar improvement effect, at the same content. However, in order to reduce metal contamination, inorganic compounds are preferable over metal compounds.

To the contrary, in the case of Comparative Example 1, since the compound having a phosphate group of the present invention is not included, the polishing speed of a silicon nitride film was lower than the examples. In addition, Comparative Examples 2 and 3 exhibited bad results because the contents of the polishing selectivity controlling agent did not fall within the range of the present invention.

### Comparative Examples 4 to 5 and Reference Examples 1 to 6: Preparation of Slurries Including Primary to Tertiary Amine Compounds

An experiment was conducted to confirm the effects of using primary, secondary, and tertiary amine compounds as an agent for controlling polishing selectivity as shown in the following Table 4. An abrasive (90 nm colloidal silica), a catalyst (ferrosilicon), an agent for controlling polishing selectivity (the component of Table 4), a biocide (methylisothiazolinone), and distilled water were stirred in a mechanical stirrer and mixed. The content of biocide in the slurry composition was 0.01 wt %.

After the stirring was completed, nitric acid and TMAH were used as pH adjusting agents to adjust the pH of the slurry composition to 2. Further, before polishing a semiconductor film, 3 wt % of 31% hydrogen peroxide was additionally added to the composition of which pH had been adjusted, thus preparing the slurry compositions of Comparative Examples 4 to 5 and Reference Examples 1 to 6, and a polishing test was progressed as explained above. The compositions using the primary amine and secondary amine as an agent for controlling polishing selectivity were respectively designated as Comparative Example 4 and Comparative Example 5.

TABLE 4

| | | | Agent for controlling | | | | |
|---|---|---|---|---|---|---|---|
| | Abrasive | | polishing selectivity | | Catalyst | | |
| | | content | | content | | content | |
| | component | (wt %) | component | (wt %) | component | (wt %) | pH |
| Comparative | silica | 4 | Ethylamine | 0.10 | ferro- | 0.003 | 2 |
| Example 4 | | | | | silicon | | |
| Comparative | silica | 4 | diethylamine | 0.10 | ferro- | 0.003 | 2 |
| Example 5 | | | | | silicon | | |
| Reference | silica | 4 | trimethylamine | 0.10 | ferro- | 0.003 | 2 |
| Example 1 | | | | | silicon | | |
| Reference | silica | 4 | Triethylamine | 0.10 | ferro- | 0.003 | 2 |
| Example 2 | | | | | silicon | | |
| Reference | silica | 4 | Tributylamine | 0.10 | ferro- | 0.003 | 2 |
| Example 3 | | | | | silicon | | |
| Reference | silica | 4 | Tripropylamine | 0.10 | ferro- | 0.003 | 2 |
| Example 4 | | | | | silicon | | |
| Reference | silica | 4 | Triethylamine | 0.0001 | ferro- | 0.003 | 2 |
| Example 5 | | | | | silicon | | |
| Reference | silica | 4 | Triethylamine | 1.000 | ferro- | 0.003 | 2 |
| Example 6 | | | | | silicon | | |

For the slurry compositions of Comparative Examples 4 to 5 and Reference Examples 1 to 6, the measurement results of the polishing speeds are shown in the following Table 5.

TABLE 5

| | | | | Selectivity | | |
|---|---|---|---|---|---|---|
| No. | Si₃N₄ | SiO₂ | W | Si₃N₄ | SiO₂ | W |
| Comparative | 102 | 42 | 981 | 1.0 | 0.4 | 9.6 |
| Example 4 | | | | | | |
| Comparative | 97 | 41 | 920 | 1.0 | 0.4 | 9.5 |
| Example 5 | | | | | | |
| Reference | 111 | 178 | 933 | 1.0 | 1.6 | 8.4 |
| Example 1 | | | | | | |
| Reference | 105 | 165 | 919 | 1.0 | 1.6 | 8.8 |
| Example 2 | | | | | | |
| Reference | 99 | 188 | 945 | 1.0 | 1.9 | 9.5 |
| Example 3 | | | | | | |
| Reference | 113 | 153 | 972 | 1.0 | 1.4 | 8.6 |
| Example 4 | | | | | | |
| Reference | 117 | 98 | 992 | 1.0 | 0.8 | 8.5 |
| Example 5 | | | | | | |
| Reference | 105 | 209 | 988 | 1.0 | 2.0 | 9.4 |
| Example 6 | | | | | | |

From the results of Table 5, it can be seen that in case a tertiary amine compound is included as an agent for controlling polishing selectivity like Reference Examples 1 to 6, the polishing speed of a silicon oxide film can be effectively increased, compared to the cases of including a primary amine compound and a secondary amine compound (Comparative Examples 4 and 5). Further, in the case of Reference Examples 1 to 6, the polishing speed of a silicon oxide film was effectively increased without influencing a silicon nitride film and a tungsten film, and in the case of Reference Example 6, with the increase in the content of a tertiary amine compound, the polishing speed of a silicon oxide film was further increased.

### Comparative Examples 6 to 8 and Examples 12 to 18: Preparation of Slurry Including a Compound Having a Phosphate Group and a Tertiary Amine Compound

An experiment was progressed to prove more excellent effects obtained by the additional inclusion of a tertiary amine compound besides a compound having a phosphate group as the agents for controlling polishing selectivity, through the results of Table 5.

An abrasive (70 nm colloidal silica), a catalyst (iron nitrate, ferrosilicon), an agent for controlling polishing selectivity (the component of Table 6), a biocide (methylisothiazolinone), and distilled water were stirred in a mechanical stirrer and mixed. The content of biocide in the slurry composition was 0.01 wt %.

After the stirring was completed, nitric acid and TMAH were used as pH adjusting agents to adjust the pH of the slurry composition to 3. Before polishing a semiconductor film, 3 wt % of 31% hydrogen peroxide was additionally added to the composition of which pH had been adjusted, thus preparing the slurry compositions of Comparative Examples 7 to 8 and Examples 12 to 18, and the polishing test was progressed as explained above. The composition without an agent for controlling polishing selectivity was designated as Comparative Example 6.

TABLE 6

| | | | Agent for controlling | | | | |
|---|---|---|---|---|---|---|---|
| | Abrasive | | polishing selectivity | | Catalyst | | |
| | | Content | | Content | | Content | |
| | Component | (wt %) | Component | (wt %) | Component | (wt %) | pH |
| Comparative | silica | 2 | — | | ferro- | 0.004 | 3 |
| Example 6 | | | | | silicon | | |
| Comparative | silica | 2 | inositol | 0.06 | ferro- | 0.004 | 3 |
| Example 7 | | | hexaphosphate | | silicon | | |
| | | | Tributylamine | 0.012 | | | |
| Comparative | silica | 2 | inositol | 0.06 | ferro- | 0.004 | 3 |
| Example 8 | | | hexaphosphate | | silicon | | |
| | | | Tributylamine | 0.35 | | | |
| Example 12 | silica | 2 | inositol | 0.06 | ferro- | 0.004 | 3 |
| | | | hexaphosphate | | silicon | | |
| | | | Tributylamine | 0.015 | | | |
| Example 13 | silica | 2 | inositol | 0.06 | ferro- | 0.004 | 3 |
| | | | hexaphosphate | | silicon | | |
| | | | Tributylamine | 0.04 | | | |
| Example 14 | silica | 2 | inositol | 0.06 | ferro- | 0.004 | 3 |
| | | | hexaphosphate | | silicon | | |
| | | | Tributylamine | 0.06 | | | |
| Example 15 | silica | 2 | inositol | 0.06 | ferro- | 0.004 | 3 |
| | | | hexaphosphate | | silicon | | |
| | | | Tributylamine | 0.18 | | | |
| Example 16 | silica | 2 | inositol | 0.06 | ferro- | 0.004 | 3 |
| | | | hexaphosphate | | silicon | | |
| | | | Tributylamine | 0.3 | | | |
| Example 17 | silica | 2 | monoammonium | 0.06 | ferro- | 0.004 | 3 |
| | | | phosphate | | silicon | | |
| | | | Triethylamine | 0.18 | | | |
| Example 18 | silica | 2 | Trisodium | 0.06 | ferro- | 0.004 | 3 |
| | | | phosphate | | silicon | | |
| | | | Triethylamine | 0.18 | | | |

For the slurry compositions of Comparative Examples 6 to 8 and Examples 12 to 18, the measurement results of polishing speed and selectivity are shown in the following Table 7.

TABLE 7

| | | | | Selectivity | | |
|---|---|---|---|---|---|---|
| No. | Si₃N₄ | SiO₂ | W | Si₃N₄ | SiO₂ | W |
| Comparative | 87 | 34 | 1128 | 1.0 | 0.4 | 13.0 |
| Example 6 | | | | | | |
| Comparative | 240 | 99 | 1200 | 1.0 | 0.4 | 5.0 |
| Example 7 | | | | | | |
| Comparative | 235 | 513 | 1178 | 1.0 | 2.2 | 5.0 |
| Example 8 | | | | | | |
| Example 12 | 231 | 122 | 1169 | 1.0 | 0.5 | 5.1 |
| Example 13 | 244 | 136 | 1320 | 1.0 | 0.6 | 5.4 |
| Example 14 | 228 | 177 | 1198 | 1.0 | 0.8 | 5.3 |
| Example 15 | 220 | 375 | 1143 | 1.0 | 1.7 | 5.2 |
| Example 16 | 218 | 429 | 1255 | 1.0 | 2.0 | 5.8 |
| Example 17 | 209 | 361 | 1134 | 1.0 | 1.7 | 5.4 |
| Example 18 | 198 | 370 | 1202 | 1.0 | 1.9 | 6.1 |

From Table 7, it can be confirmed that in case the insulating film and metal film of a semiconductor substrate are polished using the slurry compositions of Examples 12 to 18, compared to the slurry compositions of Comparative Examples 6 to 8, the polishing speed of an insulating film such as a silicon nitride film and a silicon oxide film may be increased and selectivity may be controlled.

That is, it can be seen that when the slurry composition includes a) one or more compounds selected from the group consisting of a cyclic compound having a phosphate group, an inorganic compound having a phosphate group, and a metal compound having a phosphate group, and b) a tertiary amine compound as the agents for controlling polishing selectivity at a weight ratio of 1:0.25 to 1:5, an excellent effect is exhibited.

What is claimed is:

1. A chemical mechanical polishing slurry composition comprising:
1) an abrasive; and
2) an agent for controlling polishing selectivity selected from the group consisting of a) a compound having one or more phosphate groups selected from the group consisting of a cyclic compound having a phosphate group, an inorganic compound having a phosphate group, and a metal compound having a phosphate group, b) a tertiary amine compound, and c) a mixture thereof.

2. The chemical mechanical polishing slurry composition according to claim 1, wherein the cyclic compound having a phosphate group is an alicyclic compound.

3. The chemical mechanical polishing slurry composition according to claim 1, wherein the cyclic compound having a phosphate group is one or more selected from the group consisting of inositol monophosphate, inositol biphosphate, inositol triphosphate, inositol tetraphosphate, inositol pentakisphosphate, inositol hexaphosphate, glucose 1-phosphate, and glucose 6-phosphate.

4. The chemical mechanical polishing slurry composition according to claim 1, wherein the inorganic compound having a phosphate group is one or more selected from the group consisting of monoammonium phosphate (MAP), diammonium phosphate (DSP), and triammonium phosphate (TSP).

5. The chemical mechanical polishing slurry composition according to claim 1, wherein the metal compound having a phosphate group is one or more selected from the group consisting of monosodium phosphate (MSP), disodium phosphate (DSP), and trisodium phosphate (TSP).

6. The chemical mechanical polishing slurry composition according to claim 1, wherein the agent for controlling polishing selectivity controls the polishing speed of a silicon nitride film.

7. The chemical mechanical polishing slurry composition according to claim 1, wherein the tertiary amine compound is one or more selected from the group consisting of trimethylamine, triethylamine, tributylamine, and tripropylamine.

8. The chemical mechanical polishing slurry composition according to claim 1, wherein the mixture c) comprises the compound a) having a phosphate group and the tertiary amine compound c) at a weight ratio of 1:0.25 to 1:5.

9. The chemical mechanical polishing slurry composition according to claim 1, wherein the slurry composition further comprises a catalyst.

10. The chemical mechanical polishing slurry composition according to claim 9, wherein the catalyst is included in the content of 0.00001 to 1 wt %, based on the total weight of the slurry composition.

11. The chemical mechanical polishing slurry composition according to claim 1, wherein the slurry composition further comprises one or more pH adjusting agents.

12. The chemical mechanical polishing slurry composition according to claim 1, wherein the slurry composition further comprises one or more biocides.

13. The chemical mechanical polishing slurry composition according to claim 1, wherein the slurry composition further comprises one or more reaction controllers.

14. The chemical mechanical polishing slurry composition according to claim 1, wherein the slurry composition further comprises water, alcohol, or a mixture thereof.

15. The chemical mechanical polishing slurry composition according to claim 1, wherein the slurry composition further comprises one or more oxidizing agents.

16. The chemical mechanical polishing slurry composition according to claim 1, wherein the abrasive is included in the content of 0.01 to 10 wt %, based on the total weight of the slurry composition.

17. The chemical mechanical polishing slurry composition according to claim 1, wherein the agent for controlling polishing selectivity is included in the content of 0.0001 to 10 wt %, based on the total weight of the slurry composition.

18. A chemical mechanical polishing slurry composition comprising, based on the total weight of the slurry composition, 0.01 to 10 wt % of an abrasive, 0.0001 to 10 wt % of an agent for controlling polishing selectivity, 0.00001 to 1 wt % of a catalyst, 0.0005 to 5 wt % of a pH adjusting agent, 0.0001 to 0.1 wt % of a biocide, and the remaining amount of water.

19. The chemical mechanical polishing slurry composition according to claim 18, further comprising a reaction controller in the content of 0.0001 to 1 wt %, based on the total weight of the slurry composition.

20. The chemical mechanical polishing slurry composition according to claim 18, further comprising an oxidizing agent in the content of 0.005 to 10 wt %, based on the total weight of the slurry composition.

21. A method for polishing a semiconductor substrate, comprising:
a) a process of polishing an insulating film or a metal film formed on a semiconductor substrate; or
b) a process of simultaneously polishing an insulating film and a metal film formed on a semiconductor substrate,
by using the chemical mechanical polishing slurry composition according to claim 1.

22. The method for polishing a semiconductor substrate according to claim 21, wherein the insulating film includes a silicon nitride film, a silicon oxide film, or both a silicon nitride film and a silicon oxide film.

23. The method for polishing a semiconductor substrate according to claim 21, wherein the metal film is a tungsten film.

24. The method for polishing a semiconductor substrate according to claim 21, wherein, in case the insulating film in the process b) is a silicon nitride film or a silicon oxide film, polishing selectivity between the silicon nitride film or silicon oxide film, and the metal film, is 1:3 or more.

25. The method for polishing a semiconductor substrate according to claim 21, wherein, in case the insulating film in the process b) includes a silicon nitride film and a silicon oxide film, polishing selectivity among the silicon nitride film, the silicon oxide film, and the metal film is 1:0.5 to 2:3 to 10.
